(19) United States
(12) Patent Application Publication
(10) Pub. No.: US 2016/0111618 A1
(43) Pub. Date: Apr. 21, 2016

(54) OPTOELECTRONIC DEVICE INCLUDING IMPROVED THERMAL MANAGEMENT

(71) Applicant: SENSOR ELECTRONIC TECHNOLOGY, INC., Columbia, SC (US)

(72) Inventors: Michael Shur, Latham, NY (US); Maxim S. Shatalov, Columbia, SC (US); Alexander Dobrinsky, Loudonville, NY (US); Remigijus Gaska, Columbia, SC (US)

(73) Assignee: SENSOR ELECTRONIC TECHNOLOGY, INC., Columbia, SC (US)

(21) Appl. No.: 14/706,141

(22) Filed: May 7, 2015

Related U.S. Application Data
(60) Provisional application No. 61/989,905, filed on May 7, 2014.

(51) Int. Cl. H01L 33/64; H01L 33/00

(52) U.S. Cl. CPC H01L 33/641; H01L 33/002; H01L 33/642; H01L 33/005

(57) ABSTRACT

A heterostructure for use in fabricating an optoelectronic device with improved thermal management is provided. The heterostructure can include a plurality of epitaxially grown layers including an n-type contact layer, an active layer, and a p-type contact layer. N-type and p-type electrodes for the n-type contact layer and p-type contact layer, respectively, can be embedded within an electrically insulating, thermally conductive semiconductor layer that is adjacent to the epitaxially grown layers. The electrically insulating, thermally conductive semiconductor layer can provide a larger lateral area for extracting heat generated by the active layer, so that there is improved thermal management within the device.

### REFERENCE TO RELATED APPLICATIONS

The current application claims the benefit of co-pending U.S. Provisional Application No. 61/989,905, titled “Optoelectronic Device with Improved Thermal Management,” which was filed on 7 May 2014, and which is hereby incorporated by reference.

### TECHNICAL FIELD

The disclosure relates generally to optoelectronic devices, and more particularly, to optoelectronic devices with improved thermal management.

### BACKGROUND ART

Group III nitride semiconductors are widely used for efficient blue and ultraviolet light emitting diodes, lasers, ultraviolet detectors, and field effect transistors. Due to a wide band-gap, these materials are one of the prime choices for deep ultraviolet light emitting diodes (DUV LEDs). While in recent years significant advances have been made in improving efficiency of DUV LEDs, efficiencies of these devices are still low. Due to the low efficiencies of these devices, most of the applied power is converted into heat, which results in low reliability and an additional decrease in efficiency of these devices.

UV LED lifetime, reliability and efficiency degrade rapidly with temperature increase. For example, FIG. 1 shows a decrease in output of optical power for a 280 nm UV LED as a function of temperature according to the prior art. For temperature increase of 25° C. above the ambient, the power output decreases by about 40%. Similarly, reliability and efficiency of the UV LED suffer due to an increase in temperature. In order to improve thermal management of the device, several steps have been utilized:
1. incorporation of heatsink for adequate thermal energy dissipation into the ambient;
2. decreasing the thermal resistance of the package containing the UV LED by improving package design, by utilizing high thermal conductivity materials, and by incorporating low thermal resistance interfaces between package and heat sink, package and submount containing the LED, and the LED and submount; and
3. finally, the overall thermal resistance of the UV LED can be optimized through improvements in design of the LED chip.

One of the improvements in thermal management due to placing and design of the LED chip is achieved through flip chip technology which is currently employed for manufacturing UV LEDs manufactured by Sensor Electronic Technology, Inc. FIG. 2 shows a schematic design of an illustrative emitting device 10 which is configured to operate as a light emitting diode (LED), such as a conventional or super luminescent LED, according to the prior art. Alternatively, the emitting device 10 can be configured to operate as a laser diode (LD). In either case, the emitting device 10 includes a heterostructure 11 comprising a substrate 12, a buffer layer 14 adjacent to the substrate 12, an n-type cladding layer 16 (e.g., an electron supply layer) adjacent to the buffer layer 14, and an active region 18 having an n-type side 19A adjacent to the n-type cladding layer 16. Furthermore, the heterostructure 11 of the emitting device 10 includes a first p-type layer 20 (e.g., an electron blocking layer) adjacent to a p-type side 19B of the active region 18 and a second p-type layer 22 (e.g., a hole supply layer) adjacent to the first p-type layer 20. The DUV LED device semiconductor layers can comprise group III nitride materials comprising in turn one or more group III elements (e.g., boron (B), aluminum (Al), gallium (Ga), and indium (In)) and nitrogen (N), such that BwAlxGayInzN, where 0≦W, X, Y, Z≦1, and W+X+Y+Z=1. Illustrative group III nitride materials include AlN, GaN, InN, BN, AlGaN, AlInN, AlBN, AlGaInN, AlGaBN, AlInBN, and AlGaInBN with any molar fraction of group III elements.

As shown with respect to the emitting device 10, a p-type metal 24 can be attached to the second p-type layer 22 and a p-type contact (electrode) 26 can be attached to the p-type metal 24. Similarly, an n-type metal 28 can be attached to the n-type layer 16 and an n-type contact (electrode) 30 can be attached to the n-type metal 28. The p-type metal 24 and the n-type metal 28 can form ohmic contacts to the corresponding layers 22, 16, respectively. Typically, the p-type metal 24 and the n-type metal 28 each comprise several conductive and reflective metal layers, while the n-type contact 30 and the p-type contact 26 each comprise highly conductive metal.

Regardless, the device 10 is mounted in a flip chip configuration where the p-type and n-type metal contacts 26, 30 are attached to an insulating highly thermally conducting submount 36, which, for example, can comprise SiC via contact pads 32, 34, respectively. Such flip chip configuration leads to thermal dissipation of heat through the p-type and n-type contacts 26, 30; however most of the dissipation occurs through the p-type contact 26, since the thermal path through the n-type contact 30 contains highly thermally resistive regions.

### SUMMARY OF THE INVENTION

The inventors propose a solution to increase the thermal conductivity through the n-contact 30, e.g., by employing an embedding matrix layer. Aspects of the invention provide a heterostructure for use in fabricating an optoelectronic device with improved thermal management. An embodiment of the heterostructure includes a plurality of epitaxially grown layers including an n-type contact layer, an active layer, and a p-type contact layer. N-type and p-type electrodes for the n-type contact layer and p-type contact layer, respectively, can be embedded within an electrically insulating, thermally conductive semiconductor layer that is adjacent to the epitaxially grown layers. The electrically insulating, thermally conductive semiconductor layer provides a larger lateral area for extracting heat generated by the active layer.

A first aspect of the invention provides a heterostructure comprising: a plurality of epitaxially grown layers, including: an n-type contact layer; and a mesa region adjacent to the n-type contact layer, the mesa region comprising an active layer and a p-type contact layer; an n-type electrode to the n-type contact layer; a p-type electrode to the p-type contact layer; and an electrically insulating, thermally conductive semiconductor layer adjacent to the mesa region, wherein a thermal conductivity of the electrically insulating, thermally conductive semiconductor layer is at least five percent of the thermal conductivity of at least one of the plurality of epitaxially grown layers.

A second aspect of the invention provides an optoelectronic device comprising: a plurality of epitaxially grown layers, including: a substrate; an n-type contact layer to the substrate; and a mesa region adjacent to the n-type contact layer, the mesa region comprising an active layer and a p-type contact layer; an n-type electrode to the n-type contact layer; a p-type electrode to the p-type contact layer; and an electrically insulating, thermally conductive semiconductor layer adjacent to the mesa region, wherein a thermal conductivity of the electrically insulating, thermally conductive semiconductor layer is at least five percent of the thermal conductivity of at least one of the plurality of epitaxially grown layers.

A third aspect of the invention provides a method of fabricating a device, the method comprising: epitaxially growing a plurality of layers on a substrate, wherein the plurality of layers includes: a substrate; an n-type contact layer to the substrate; a mesa region adjacent to the n-type contact layer, the mesa region comprising an active layer and a p-type contact layer; and an electrically insulating, thermally conductive semiconductor layer adjacent to the mesa region, wherein a thermal conductivity of the electrically insulating, thermally conductive semiconductor layer is at least five percent of the thermal conductivity of at least one of the plurality of epitaxially grown layer.

The illustrative aspects of the invention are designed to solve one or more of the problems herein described and/or one or more other problems not discussed.

### BRIEF DESCRIPTION OF THE DRAWINGS

These and other features of the disclosure will be more readily understood from the following detailed description of the various aspects of the invention taken in conjunction with the accompanying drawings that depict various aspects of the invention.

FIG. 1 shows an illustrative plot showing a decrease in output of optical power for a device as a function of temperature according to the prior art.

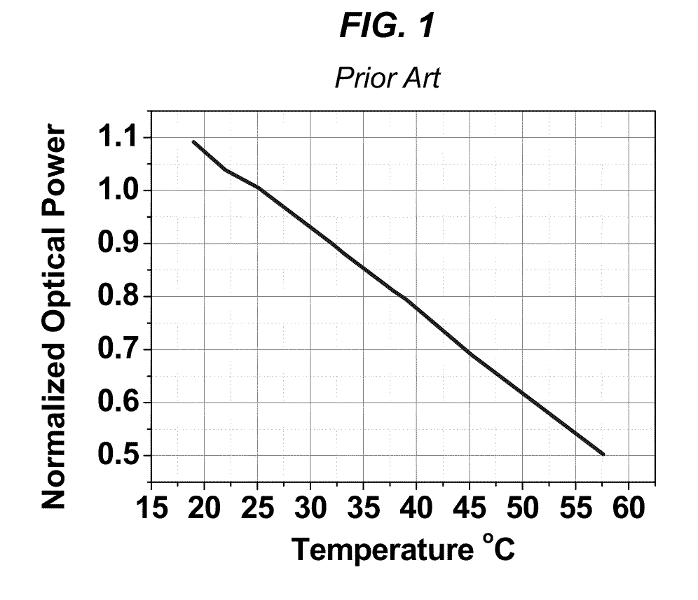

FIG. 2 shows a schematic structure of an optoelectronic device according to the prior art.

FIG. 3 shows a schematic structure of an illustrative optoelectronic device according to an embodiment.

FIG. 4 shows a schematic illustration of a mesa region and a thermal spreading region according to an embodiment.

FIGS. 5A-5C show illustrative plots of the dependence of the thermal resistance on the mesa area, the spreading area on the mesa area, and the ratio of the spreading area to the mesa area on the mesa area according to an embodiment.

FIGS. 6A and 6B shows schematic structures of an illustrative device including pixel mesa regions according to an embodiment.

FIG. 7 shows a schematic structure of an illustrative optoelectronic device according to an embodiment.

FIG. 8 shows a schematic structure of an illustrative optoelectronic device according to an embodiment.

FIG. 9 shows a schematic structure of an illustrative optoelectronic device according to an embodiment.

FIG. 10 shows a schematic structure of an illustrative optoelectronic device within a package according to an embodiment.

FIG. 11 shows a schematic structure of an illustrative optoelectronic device within a package according to an embodiment.

FIG. 12 shows an illustrative flow diagram for fabricating a circuit according to an embodiment.

It is noted that the drawings may not be to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

As indicated above, aspects of the invention provide a heterostructure for use in fabricating an optoelectronic device with improved thermal management. An embodiment of the heterostructure includes a plurality of epitaxially grown layers including an n-type contact layer, an active layer, and a p-type contact layer. N-type and p-type electrodes for the n-type contact layer and p-type contact layer, respectively, can be embedded within an electrically insulating, thermally conductive semiconductor layer that is adjacent to the epitaxially grown layers. The electrically insulating, thermally conductive semiconductor layer provides a larger lateral area for extracting heat generated by the active layer, e.g., to provide improved thermal management within the device.

As used herein, unless otherwise noted, the term “set” means one or more (i.e., at least one) and the phrase “any solution” means any now known or later developed solution. As also used herein, a layer is a transparent layer when the layer allows at least ten percent of radiation having a target wavelength, which is radiated at a normal incidence to an interface of the layer, to pass there through. Furthermore, as used herein, a layer is a reflective layer when the layer reflects at least ten percent of radiation having a target wavelength, which is radiated at a normal incidence to an interface of the layer. In an embodiment, the target wavelength of the radiation corresponds to a wavelength of radiation emitted or sensed (e.g., peak wavelength +/−five nanometers) by an active region of an optoelectronic device during operation of the device. For a given layer, the wavelength can be measured in a material of consideration and can depend on a refractive index of the material. Additionally, as used herein, a contact is considered “ohmic” when the contact exhibits close to linear current-voltage behavior over a relevant range of currents/voltages to enable use of a linear dependence to approximate the current-voltage relation through the contact region within the relevant range of currents/voltages to a desired accuracy (e.g., +/−one percent). It is understood that, unless otherwise specified, each value is approximate and each range of values included herein is inclusive of the end values defining the range.

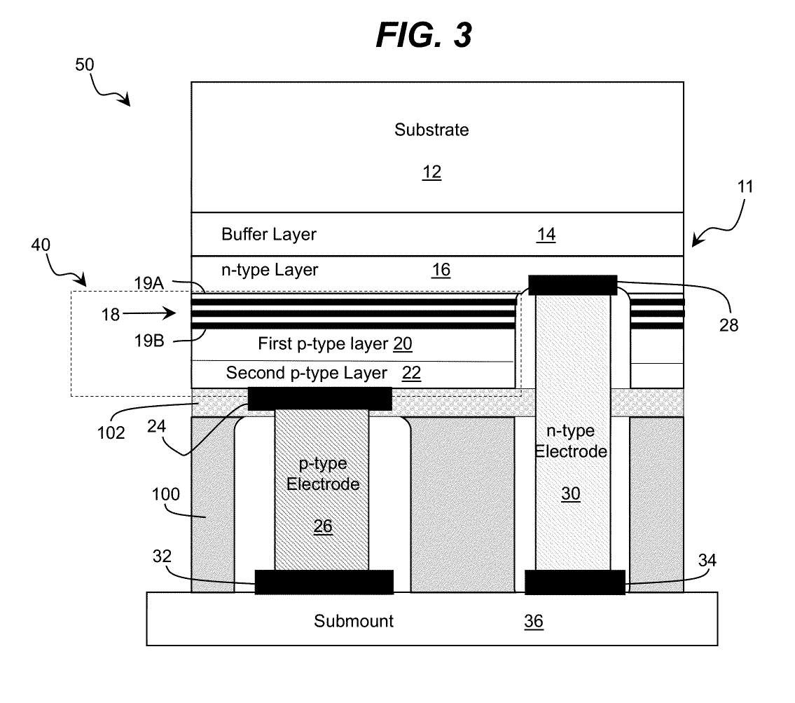

Turning to the drawings, FIG. 3 shows a schematic structure of an illustrative optoelectronic device 50 according to an embodiment. In a more particular embodiment, the optoelectronic device 50 is configured to operate as an emitting device, such as a light emitting diode (LED) or a laser diode (LD). In either case, during operation of the optoelectronic device 50, application of a bias comparable to the band gap results in the emission of electromagnetic radiation from an active region 18 of the optoelectronic device 50. The electromagnetic radiation emitted (or sensed) by the optoelectronic device 50 can have a peak wavelength within any range of wavelengths, including visible light, ultraviolet radiation, deep ultraviolet radiation, infrared light, and/or the like. In an embodiment, the device 50 is configured to emit (or sense) radiation having a dominant wavelength within the ultraviolet range of wavelengths. In a more specific embodiment, the dominant wavelength is within a range of wavelengths between approximately 210 and approximately 360 nanometers.

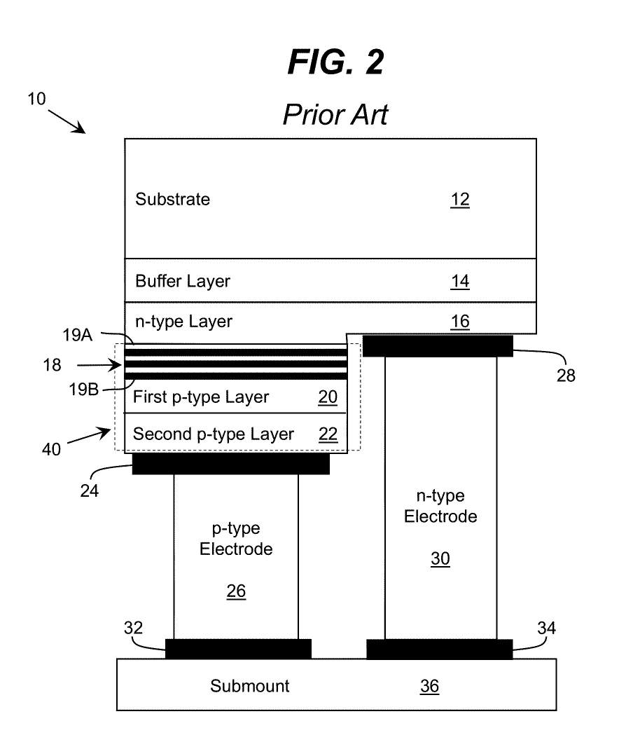

Similar to the optoelectronic device 10 shown in FIG. 2, the optoelectronic device 50 includes a heterostructure 11 comprising a substrate 12, a buffer layer 14 adjacent to the substrate 12, an n-type layer 16 (e.g., a cladding layer, electron supply layer, contact layer, and/or the like) adjacent to the buffer layer 14, and an active region 18 having an n-type side 19A adjacent to the n-type layer 16. Furthermore, the heterostructure 11 of the optoelectronic device 50 includes a first p-type layer 20 (e.g., an electron blocking layer, a cladding layer, hole supply layer, and/or the like) adjacent to a p-type side 19B of the active region 18 and a second p-type layer 22 (e.g., a cladding layer, hole supply layer, contact layer, and/or the like) adjacent to the first p-type layer 20.

In a more particular illustrative embodiment, the optoelectronic device 50 is a group III-V materials based device, in which some or all of the various layers are formed of elements selected from the group III-V materials system. In a still more particular illustrative embodiment, the various layers of the optoelectronic device 50 are formed of group III nitride based materials. Group III nitride materials comprise one or more group III elements (e.g., boron (B), aluminum (Al), gallium (Ga), and indium (In)) and nitrogen (N), such that BwAlxGayInzN, where 0≦W, X, Y, Z≦1, and W+X+Y+Z=1. Illustrative group III nitride materials include binary, ternary and quaternary alloys such as, AlN, GaN, InN, BN, AlGaN, AlInN, AlBN, AlGaInN, AlGaBN, AlInBN, and AlGaInBN with any molar fraction of group III elements.

An illustrative embodiment of a group III nitride based optoelectronic device 50 includes an active region 18 (e.g., a series of alternating quantum wells and barriers) composed of In_{y}AlₓGa_{1-x-y}N, Ga_{z}In_{y}AlₓB_{1-x-y-z}N, an AlₓGa₁₋ₓN semiconductor alloy, or the like. Similarly, the n-type layer 16, the first p-type layer 20, and the second p-type layer 22 can be composed of an In_{y}AlₓGa_{1-x-y}N alloy, a Ga_{z}In_{y}AlₓB_{1-x-y-z}N alloy, or the like. The molar fractions given by x, y, and z can vary between the various layers 16, 18, 20, and 22. In an embodiment, the n-type layer 16 can comprise AlₓGa₁₋ₓN, where the value of x is tailored towards the design of the active layer 18. For example, for an active layer 18 designed to emit radiation at wavelengths of approximately 280 nanometers, the value of x in the n-type layer 16 is within a range of approximately 0.35 and approximately 0.65. In a more specific embodiment, the value of x is approximately 0.5.

When the optoelectronic device 50 is configured to be operated in a flip chip configuration, such as shown in FIG. 3, the substrate 12 and buffer layer 14 should be transparent to the target electromagnetic radiation. To this extent, an embodiment of the substrate 12 is formed of sapphire, and the buffer layer 14 can be composed of AlN, an AlGaN/AlN superlattice, and/or the like. However, it is understood that the substrate 12 can be formed of any suitable material including, for example, silicon carbide (SiC), silicon (Si), bulk GaN, bulk AlN, bulk or a film of AlGaN, bulk or a film of BN, AlON, LiGaO₂, LiAlO₂, aluminum oxinitride (AlOₓN_{y}), MgAl₂O₄, GaAs, Ge, or another suitable material. Furthermore, a surface of the substrate 12 can be substantially flat or patterned using any solution.

The optoelectronic device 50 can further include a p-type contact 24, which can form an ohmic contact to the second p-type layer 22, and a p-type electrode 26 can be attached to the p-type contact 24. Similarly, the optoelectronic device 10 can include an n-type contact 28, which can form an ohmic contact to the n-type layer 16, and an n-type electrode 30 can be attached to the n-type contact 28. The p-type contact 24 and the n-type contact 28 can form ohmic contacts to the corresponding layers 22, 16, respectively.

In an embodiment, the p-type contact 24 and the n-type contact 28 each comprise several conductive and reflective metal layers, while the n-type electrode 30 and the p-type electrode 26 each comprise highly conductive metal. In an embodiment, the second p-type layer 22 and/or the p-type electrode 26 can be transparent to the electromagnetic radiation generated by the active region 18. For example, the second p-type layer 22 and/or the p-type electrode 26 can comprise a short period superlattice lattice structure, such as an at least partially transparent magnesium (Mg)-doped AlGaN/AlGaN short period superlattice structure (SPSL). Furthermore, the p-type electrode 26 and/or the n-type electrode 30 can be reflective of the electromagnetic radiation generated by the active region 18. In another embodiment, the n-type layer 16 and/or the n-type electrode 30 can be formed of a short period superlattice, such as an AlGaN SPSL, which is transparent to the electromagnetic radiation generated by the active region 18.

As further shown with respect to the optoelectronic device 50, the device 50 can be mounted to a submount 36 via the electrodes 26, 30 in a flip chip configuration. In this case, the substrate 12 is located on the top of the optoelectronic device 50. To this extent, the p-type electrode 26 and the n-type electrode 30 can both be attached to a submount 36 via contact pads 32, 34, respectively. The submount 36 can be formed of aluminum nitride (AlN), silicon carbide (SiC), and/or the like.

The device 50 also includes a semiconductor layer 100 located between the heterostructure 11 of the device 50 and the submount 36. In an embodiment, the p-type electrode 26 and n-type electrode 30 are embedded within the semiconductor layer 100. The semiconductor layer 100 is an electrically insulating, thermally conductive material and can be formed of polycrystalline aluminum nitride (AlN), Boron Nitride (BN), GaAs, diamond, silicon carbide (SiC), and/or the like. In an embodiment, the thermal conductivity of the semiconductor layer 100 is at least approximately five percent of the thermal conductivity of at least one of the layers within the heterostructure 11 (e.g., layers 12, 14, 16, 18, 20, 22). In a more specific embodiment, the thermal conductivity of the semiconductor layer 100 is at least approximately five percent of the thermal conductivity of the layer within the heterostructure 11 with the lowest thermal conductivity. In an embodiment, the thermal conductivity of the semiconductor layer 100 is higher than approximately 10 Watts per meters Kelvin (W/(mK)). In another embodiment, the semiconductor layer 100 can also be electrically conductive and be formed of a conductive metal, such as copper, silver, aluminum, chromium, nickel, and/or the like. One or both electrodes 26, 30 can be electrically insulated from the semiconductor layer 100, e.g., by a spacing between the electrode(s) 26, 30 and the semiconductor layer 100.

Referring back to the device 10 shown in FIG. 2, a lateral area of the p-type electrode 26 is only as large as the lateral area of a mesa region 40 (e.g., active layer 18, first p-type layer 20, and second p-type layer 22) and is only a fraction of the overall lateral area of the device 10. In an embodiment, the lateral area of the mesa region 40 can be approximately half of the lateral area of the device 10. The lateral area of the n-type electrode 30 is typically smaller than the lateral area of the mesa region 40. However, in an embodiment, the lateral area of the mesa region 40 is smaller than the lateral area of the n-type electrode 30 by at least approximately two percent. Since heat is mostly extracted through the p-type electrode 26 (due to its proximity to the active region 18) the larger the p-type electrode lateral area, the more heat that is extracted through p-type electrode 26. Since the n-type electrode 30 is separated from the active layer 18 (e.g., the source of the heat from the device 10), only a fraction of the overall heat generated by the device 10 is extracted through the n-type electrode 30. The exact percentage of the heat extracted through the n-type electrode 30 depends on the thickness and conductivity of the semiconductor layers, but in general, it contributes to less than 10% of the overall heat extraction.

In the device 50 shown in FIG. 3, the semiconductor layer 100 increases the lateral area that is used to extract heat from the device 50. Therefore, more heat generated by the active layer 18 of the device 50 can be extracted simultaneously (via semiconductor layer 100, p-type electrode 26, and n-type electrode 30) so that the device 50 can operate more efficiently.

The interface of the second p-type layer 22 and the semiconductor layer 100 can introduce stresses to the device 50, which can lead to reliability issues. In an embodiment, the device 50 can include an interface layer 102 located between the second p-type layer 22 and the semiconductor layer 100. The interface layer 102 can extend across the entire lateral area of the device 50, as shown in FIG. 3, or it can be located only at the interface of the p-type layer 22 and the semiconductor layer 100. An objective of the interface layer 102 is to either reduce or eliminate stresses associated with layer 22 and layer 100. The interface layer 102 can be grown using any technique, such as a 3-dimensional (3D) growth of an AlN nucleation layer at approximately 10-100 Torr at temperatures of approximately 600-1100 degrees Celsius with an average group V to group III precursor ratio on the order of approximately 10000. In a more specific embodiment, the temperature range can be between approximately 800-900 degrees Celsius. Further, through migration enhanced epitaxy that is used to promote coalescence of nucleation islands, ammonia (NH₃) can be added through a pulsed flow growth at approximately 100 Torr and temperatures of approximately 1200 degrees Celsius with a group V to group III precursor ratio of approximately 2000.

The thermal resistance of a device depends crucially on the lateral area. The junction temperature (e.g., the highest operating temperature of the device) depends on the thermal resistance of the device as well as the overall power of the device. The power dissipated by a typical device is given by: Q=JA₁V, where J (A/cm²) is the current density within the active layer, A₁ is the device mesa lateral area, and V is the constant voltage. For fixed values of J and V, the dissipated power is directly proportional to the mesa area of the device. In the device 50 shown in FIG. 3, the overall thermal resistance of the device is the resistance of three thermal channels in parallel. The first thermal channel is the p-type electrode 26, second channel is the n-type electrode 30, and the third channel is the semiconductor layer 100. The thermal conductance can be written as:

$$\frac{1}{{R}_{T}} = \frac{{k}_{p} {A}_{p}}{L} + \frac{{k}_{n} {A}_{n}}{L} + \frac{1}{{R}_{F}}$$

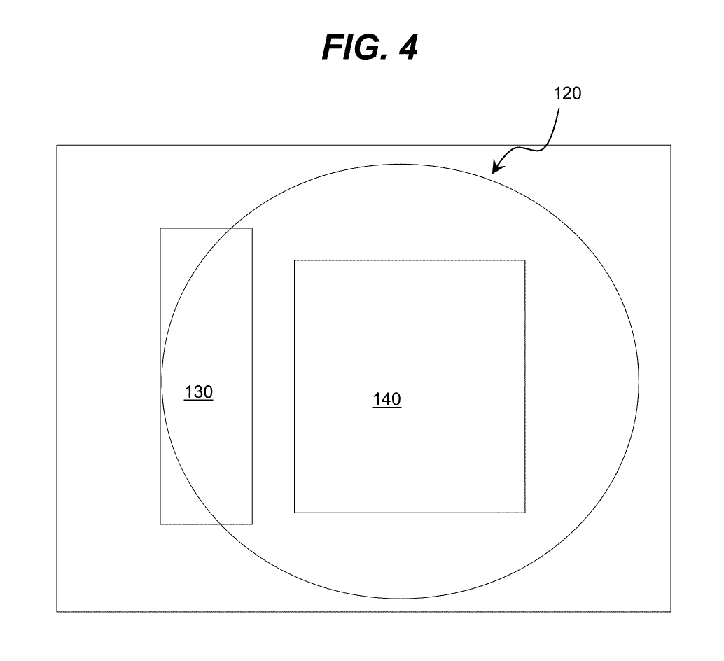

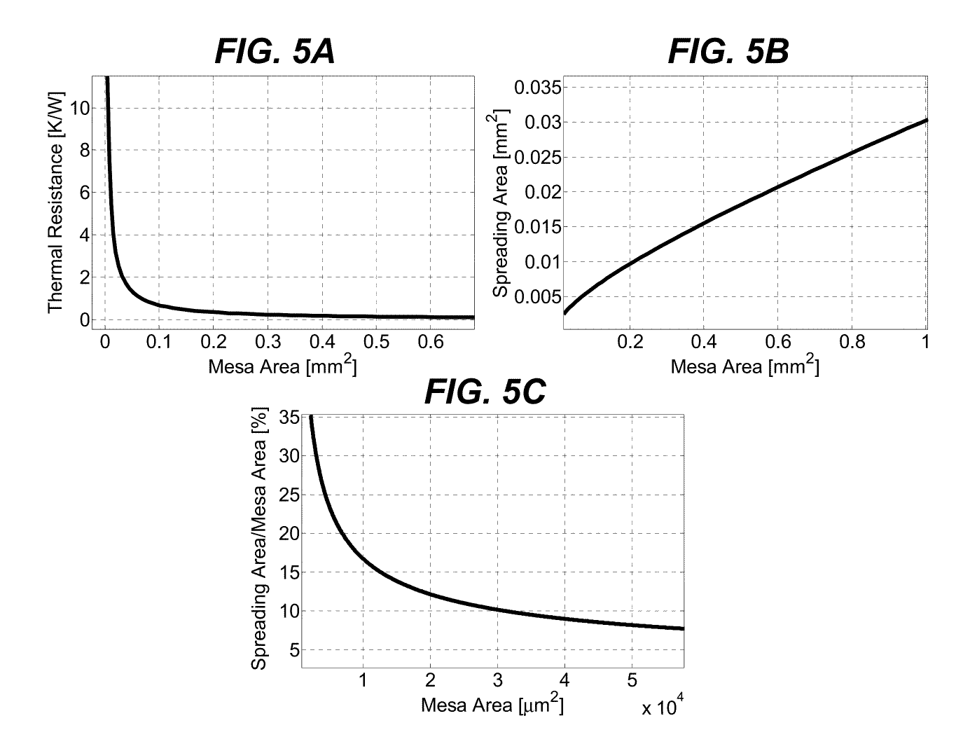

and the increase in junction temperature is given by:

$$Δ T = \frac{Q}{( \frac{1}{{R}_{T}} )} = \frac{{JA}_{m} V}{\frac{{k}_{p} {A}_{p}}{L} + \frac{{k}_{n} {A}_{n}}{L} + 1 / {R}_{M}}$$

where R_{M} is an effective thermal resistance of the semiconductor layer 100, and can be calculated taking into account the thermal spreading resistance of the layer. Here, R_{T} is the total thermal resistance, kₚ is the thermal conductivity of the p-type electrode 26, Aₚ is the lateral area of the p-type electrode 26, kₙ thermal conductivity of the n-type electrode 30, Aₙ is the lateral area of the n-type electrode 30, Aₘ is the lateral area of the mesa 40, and L is the length of the p-type electrode (n-type electrode is approximated to have the same length L). The effective thermal conductive region is schematically drawn in FIG. 4, where the region 140 corresponds to mesa 40 (FIG. 3) and region 130 is an n-type electrode (FIG. 3). Region 120 is a thermal spreading region which corresponds to the region within layer 100 that is actively transporting heat. For improved thermal conductivity, it is best for the thermal spreading to overlap with the n-type contact. The thermal resistance R_{M} can approximated using the following equation:

$${R}_{M} = ( \frac{1}{( {k}_{M} a )} ) ( \begin{matrix}0.31338 h - 0.25134 {h}^{2} + \\ 0.12512 {h}^{3} - 0.03436 {h}^{4} + 0.003908 {h}^{5}\end{matrix} )$$

where α is the effective radius of the mesa 40 and can be defined by α=\sqrt{A/π}, where A is the lateral area of the mesa 40 (FIG. 3), and h is the ratio of layer thickness to effective radius α, wherein the layer thickness includes the thickness of the mesa region 40 and the p-type electrode 30 length L; that is h=L+lₘ, where lₘ is the thickness of the mesa, and L is the length of the p-type electrode. Here k_{M} is the conductivity of the layer 100. Turning now to FIGS. 5A-5C, several plots for a device are shown. FIG. 5A shows the dependence of the thermal resistance R_{M} on the mesa area. In this example, for a device 50 shown in FIG. 3, the combined thickness of the mesa region 40 and p-type pad 32 and the p-type electrode 26 is approximately 10 microns. For illustrative purposes, the thermal conductivity of layer 100, which can be, for example, an AlN layer, is k_M˜140 W/(m·K). The thermal resistance in FIG. 5A shows how the approximation equation for R_{M} depends on lateral area of the mesa. As seen from the approximation equation for R_{M}, it has to follow hyperbolic nature. Turning now to FIG. 5B, the dependence of the spreading area on the mesa area is shown. The spreading area is typically an order of magnitude, or more, smaller than the p-type electrode area, and for large area mesas, the incorporation of the semiconductor layer 100 may result in only marginal effects. However, the importance of incorporating the semiconductor layer 100 can be seen for a device comprising pixel type mesa (small lateral area mesa), where the typical area of a single pixel is 10,000 μm². For example, for a pixel mesa having area of about 8,000 μm², it may be approximated as a circular shape, having a perimeter on the order of approximately 350 microns, with radius of approximately 50 microns, the heat spreading ring surrounding the small area mesa with having thickness on the order of approximately 4 microns. The area of such ring is estimated to be Aᵣ=(54²−50²)π=1300 μm², resulting in the spreading area to mesa ratio of 1300/8000×100%=16%. FIG. 5C shows the dependence of the ratio of the spreading area to the mesa area on the mesa area.

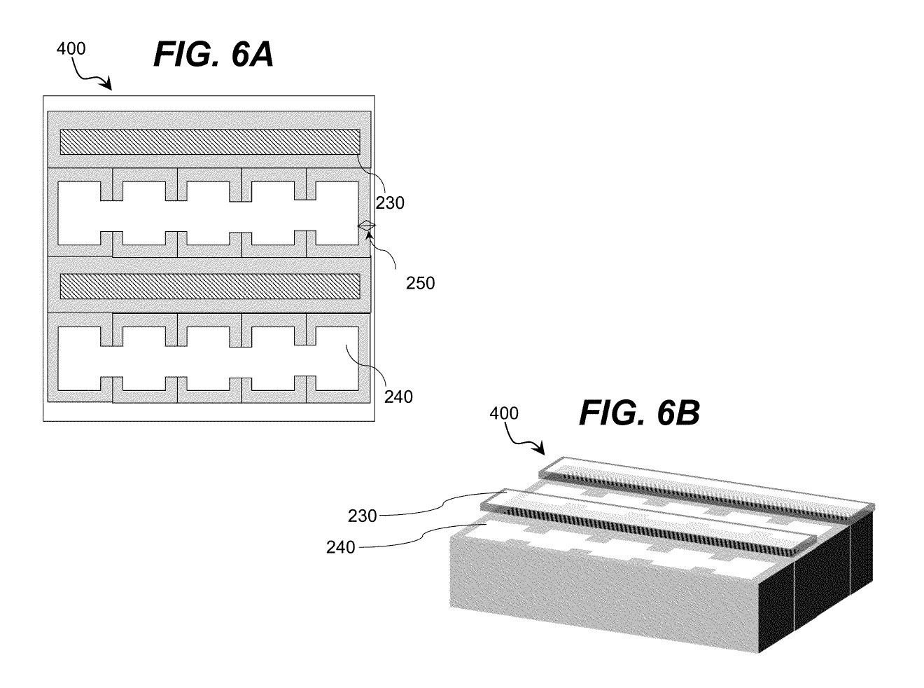

Turning now to FIGS. 6A and 6B, illustrative views of a device comprising pixel type mesa regions is shown. In FIG. 6A, the device 400 includes pixel mesa regions 240, which comprise a connected set of rectangles, and n-type electrode regions 230. It is understood that the pixel mesa areas can be made of any shape as long as they correspond to a region having a small area. It is further understood that the pixel mesa areas can be connected to form larger areas. The importance of differentiating a connected pixel mesa area and any other large area is the fact that pixel mesa areas form a domain with a significant perimeter. That is, the perimeter of the connected pixel mesa area is larger than the perimeter of a circular region having the same area. In a particular embodiment, the perimeter of the connected pixel mesa area can be 50% larger than the perimeter of a circular region having the same area. The spreading distance is shown by 250. In an embodiment, the mesa regions 240 and n-type electrode regions 230 are positioned so that they are no more than 2 current spreading lengths apart. For example, for a pixel mesa, the separation between two mesa regions or between mesa region and n-type electrode should not exceed a distance on the order of approximately 8 microns. More importantly, for large mesa areas (e.g., mesa areas larger than 0.2 mm²), and large n-type electrode areas (e.g., larger than 0.02 mm²), the effect of the semiconductor layer 100 (FIG. 3) becomes insignificant, as can be seen from FIG. 5A-FIG. 5C.

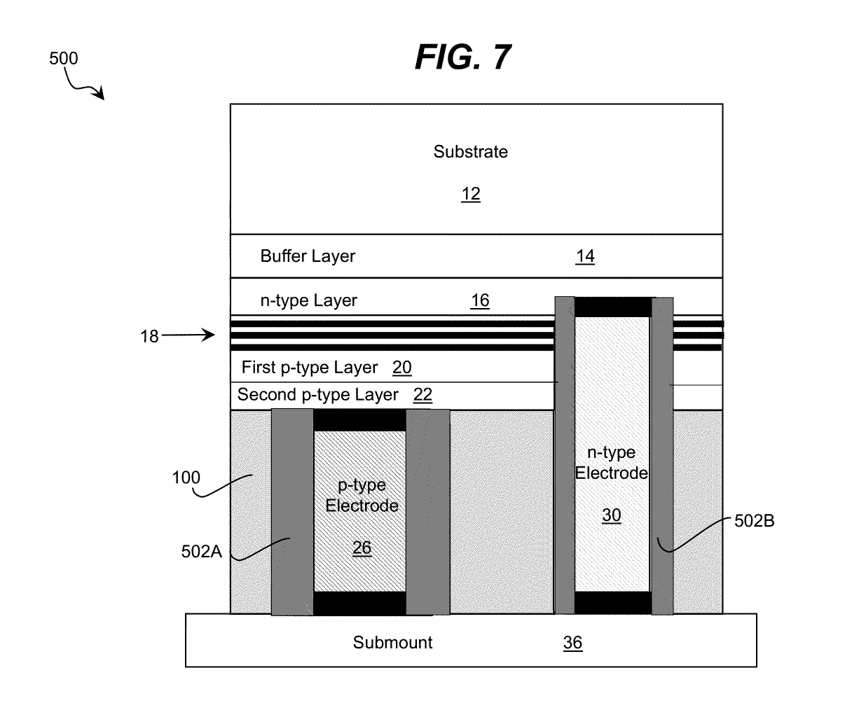

In order to further isolate the p-type electrode 26 and n-type electrode 30 (FIG. 3), a device can include an insulating material surrounding the p-type and n-type electrodes 26, 30. FIG. 7 shows a schematic structure of an illustrative device 500 according to an embodiment. The device 500 includes a semiconductor layer 100 located at the interface between the second p-type layer 22 and the p-type electrode 26, similar to the device 50 shown in FIG. 3. The device 500 also includes a first insulating material 502A located at the interface of the p-type electrode 26 and the semiconductor layer 100, and a second insulating material 502B located at the interface of the n-type electrode 30 and the semiconductor layer 100. The first and second insulating material 502A, 502B can be formed of any insulating material, such as such as silicon dioxide (SiO₂), silicon nitride (Si₃N₄), aluminum oxide, (Al₃O₂), insulating polymers, insulating resins, and/or the like. To this extent, the first and second insulating materials 502A, 502B substantially surround the p-type and n-type electrodes 26, 30, respectively. At the interface of the electrodes 26, 30 and the semiconductor layer 100, the first and second insulating materials 502A, 502B help to prevent holes and/or cavities between the semiconductor layer 100 and the p-type and n-type electrodes 26, 30. In an embodiment, the semiconductor layer 100 can comprise a material having not only high thermal conductivity, but also electrical conductivity. In this case, insulation of p-type and n-type electrodes 26, 30 prevent shorting of the device 500. Although it is not shown, the device 500 can also include an interface layer, such as the interface layer 102 shown in device 50 in FIG. 3.

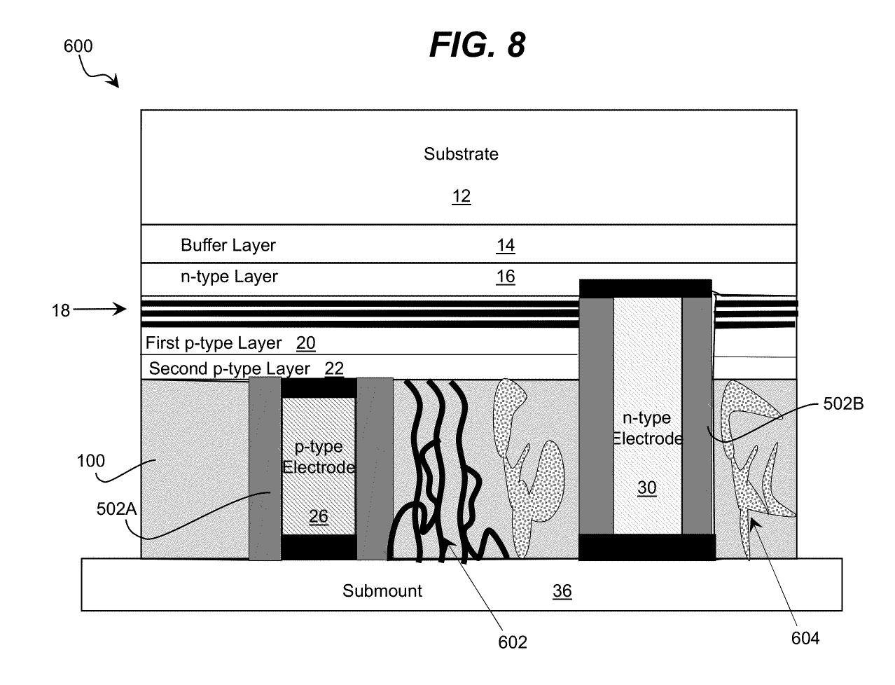

As mentioned herein, the semiconductor layer is an electrically insulating, thermally conductive material. However, the semiconductor layer can comprise composite materials. For example, FIG. 8 shows a schematic structure of an illustrative device 600 including a semiconductor layer 100 and a set of thermally conductive fillers that are embedded within the semiconductor layer 100. For example, the device 600 includes a first thermally conductive filler 602 and a second thermally conductive filler 604. The set of thermally conductive fillers can be formed of any thermally conductive material, such as diamond, AlN, SiC, BN, and/or the like.

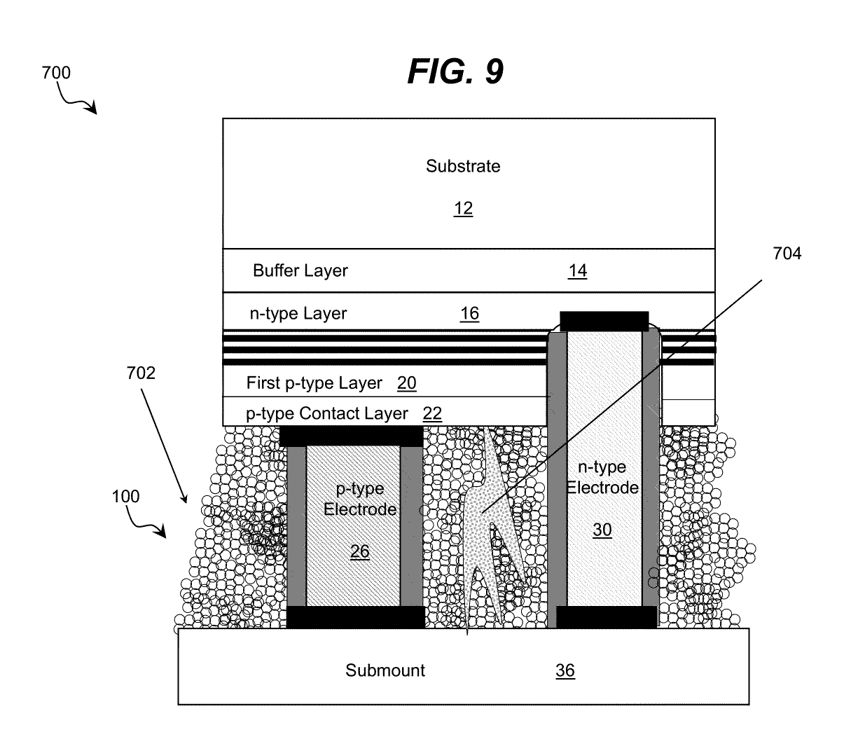

In another embodiment, as shown in FIG. 9, an illustrative device 700 can comprise a semiconductor layer 100 that includes a first thermally conductive filler 702 and a second thermally conductive filler 704. The thermally conductive fillers 702, 704 in the semiconductor layer 100 can be deposited using any technique, such as sputtering, applying a substance, such as epoxy, and/or the like, etching through an epitaxial layer, and/or the like. If the semiconductor layer 100 including the thermally conductive fillers 702, 704 is deposited by applying an epoxy, the epoxy can contain a powdered highly thermally conductive filler, such as silver particles, polycrystalline domains, and/or the like. Although not shown, both devices 600, 700 can include an interface layer, such as the interface layer 102 shown in FIG. 3. Furthermore, both devices 600, 700 can include insulating materials surrounding the p-type and/or n-type electrodes 26, 30, such as the insulating materials 502A, 502B shown in device 500 in FIG. 7.

The devices including the semiconductor layer provided herein can be fabricated using any technique. For example, referring to FIG. 3, in an embodiment, the layers 12, 14, 16, 18, 20, 22 of the heterostructure 11 can be epitaxially grown. The semiconductor layer 100 is then epitaxially grown on the p-type layer 22. In an embodiment, the interface layer 102 can be epitaxially grown between the p-type layer 22 and the semiconductor layer 100. The semiconductor layer 100 can be fabricated using sputtering, applying glue, epoxy, and/or the like, etching through the epitaxial layer, and/or the like. The semiconductor layer 100 is formed of an electrically insulating, thermally conductive material that has a thermal conductivity that is comparable or higher than a thermal conductivity of any other layer within the heterostructure 11. Next, the epitaxial layers are etched to provide contact to the n-type layer 16 and then etched to provide contact p-type layer 22. In another embodiment, the application of masking and overgrowth can be utilized to fabricate the semiconductor layer 100.

In another embodiment, to fabricate an optoelectronic device including a heterostructure, such as the heterostructure 11 shown in FIG. 3, layers 12, 14, 16, can be epitaxially grown. An area of the n-type layer 16 can be masked for forming the n-type electrode. The active layer 18 and the first and second p-type layers 20, 22 can be epitaxially grown, so that the mesa region 40 is formed. An area of the p-type layer 22 can be masked for forming the p-type electrode 26. Next, the semiconductor layer 100 can be fabricated using any technique discussed herein. The masks can be removed and the n-type and p-type electrodes 26, 30 are formed to provide contact to the n-type layer 16 and the p-type layer 22, respectively.

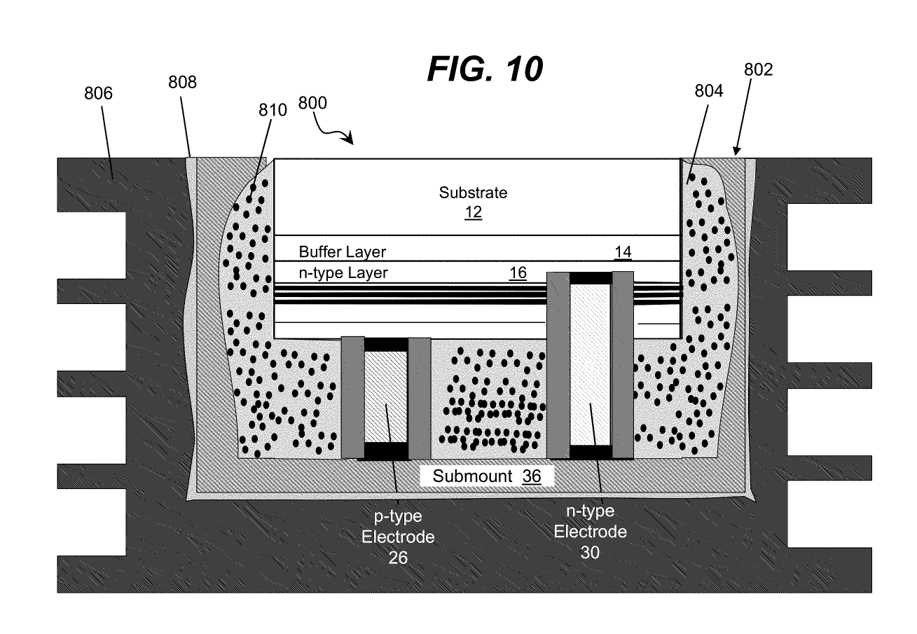

Turning now to FIG. 10, a schematic structure of an illustrative device 800 (e.g., LED) that is placed within a package 802. The package 802 can comprise a highly thermally conductive material. For example, such thermally conductive material can be a metal (such as copper having thermal conductivity of 400 W/(m·K). In another example, the package 802 can be formed of AlN, SiC, diamond, thermally conductive metals, and/or the like. The space between the device 800 and the package 802 can be filled with an electrically insulating, thermally conductive layer 804. This layer 804, similar to the semiconductor layer 100 shown in FIGS. 3 and 7-9, can comprise any thermally conductive, electrically insulating material, such as AlN, and/or the like, and include any thermally conductive filler, similar to the thermally conductive fillers 602, 604 shown in FIG. 8, such as a thermal grease, and/or any type of filler that has a good thermal conductivity. If the material of the layer 804 is also electrically conductive, the device 800 can include a layer, such as layers 502A, 502B shown in FIG. 7, to isolate the p-type and n-type electrodes 26, 30. In an embodiment, the layer 804 can contain nanoparticles 810. The nanoparticles 810 can include different metal nanoparticles and/or diamond nanoparticles.

In order to improve the heat extraction, the entire package 802, including the device 800, can be placed within a cavity containing a heat sink 806. The package 802 is tightly spaced within a cavity, and a thin layer of thermal paste 808 is used for tight coupling with a heat sink. The thermal paste 808 can be formed of silver, AlN and other material. Thermal grease can be a polymerizable liquid matrix and having thermally conductive filler. Typical matrix materials are epoxies, silicones, urethanes, and acrylates, although solvent-based systems, hot-melt adhesives, and pressure-sensitive adhesive tapes are also available. Aluminum oxide, boron nitride, zinc oxide, and aluminum nitride are used as electrically non-conductive fillers. Silver thermal compounds may have a conductivity of 3 to 8 W/(m·K) or more.

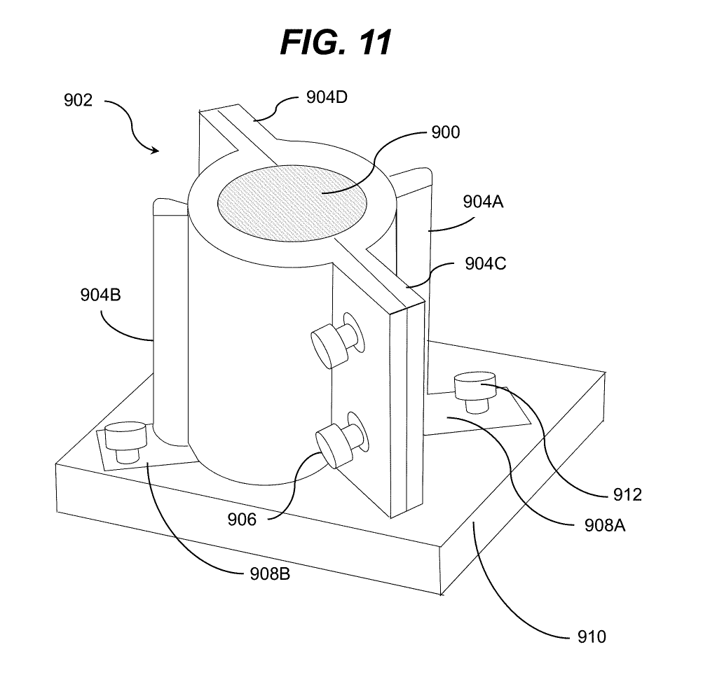

In another embodiment, the package can be tightly coupled to the heat sink using screws. Turning now to FIG. 11, a perspective view of an illustrative package 900 within a heat sink assembly 902 according to an embodiment is shown. A device, such as device 50, 400, 500, 600, 700, 800 in FIGS. 3, 6A-6B, and 7-10, can be located within the cylindrical package 900. Although the package 900 is shown as cylindrical, it is understood that the package 900 can be any shape. The heat sink assembly 902 can include a set of fins 1130A-1130D for the purpose of increasing the heat extraction through convection with the ambient air. The fins 904C, 904D can be used in combination with screws 906 to tighten the heat sink assembly 902 around the package 900. For example, as shown, the fins 904C, 904D can be tightened around the package 900 using screws 906. The fins 902A, 902B can extend into a set of supports 908A, 908B for attaching a bottom portion 910 of the heat sink assembly 902 to a remaining portion of the heat sink assembly 902. The set of supports 908A, 908B can be attached to the bottom portion 910 using any means, such as, tightening screws 912, and/or the like. It is understood that the embodiment of the package 900 within the heat sink assembly 902 shown in FIG. 11 is for illustrative purposes only and other arrangements are possible for a tight coupling of the heat sink assembly 902 and the package 900. It is also understood that, in an embodiment, at each attachment interface (e.g., using screws 906, 912), the surface of the heat sink assembly 902 can be polished and include a thin layer of thermal paste, thermal grease, and/or the like to fill in any surface variations.

While illustrative aspects of the invention have been shown and described herein primarily in conjunction with a heterostructure for an optoelectronic device and a method of fabricating such a heterostructure and/or device, it is understood that aspects of the invention further provide various alternative embodiments.

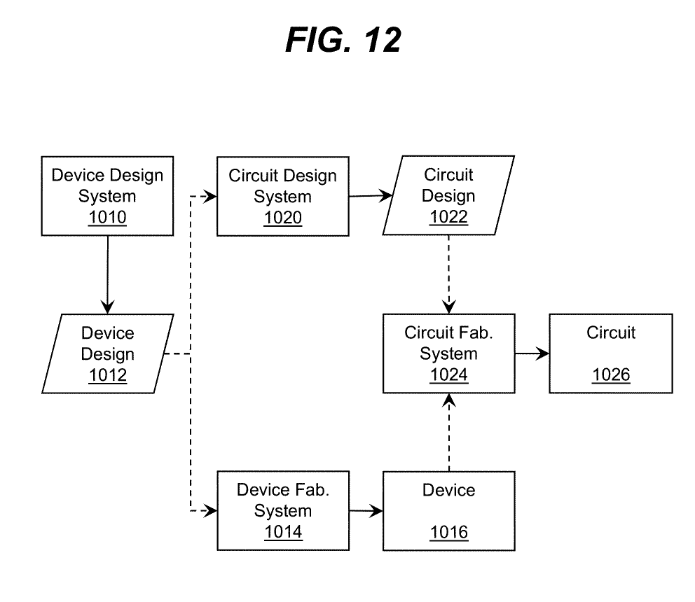

In one embodiment, the invention provides a method of designing and/or fabricating a circuit that includes one or more of the devices designed and fabricated as described herein. To this extent, FIG. 12 shows an illustrative flow diagram for fabricating a circuit 1026 according to an embodiment. Initially, a user can utilize a device design system 1010 to generate a device design 1012 for a semiconductor device as described herein. The device design 1012 can comprise program code, which can be used by a device fabrication system 1014 to generate a set of physical devices 1016 according to the features defined by the device design 1012. Similarly, the device design 1012 can be provided to a circuit design system 1020 (e.g., as an available component for use in circuits), which a user can utilize to generate a circuit design 1022 (e.g., by connecting one or more inputs and outputs to various devices included in a circuit). The circuit design 1022 can comprise program code that includes a device designed as described herein. In any event, the circuit design 1022 and/or one or more physical devices 1016 can be provided to a circuit fabrication system 1024, which can generate a physical circuit 1026 according to the circuit design 1022. The physical circuit 1026 can include one or more devices 1016 designed as described herein.

In another embodiment, the invention provides a device design system 1010 for designing and/or a device fabrication system 1014 for fabricating a semiconductor device 1016 as described herein. In this case, the system 1010, 1014 can comprise a general purpose computing device, which is programmed to implement a method of designing and/or fabricating the semiconductor device 1016 as described herein. Similarly, an embodiment of the invention provides a circuit design system 1020 for designing and/or a circuit fabrication system 1024 for fabricating a circuit 1026 that includes at least one device 1016 designed and/or fabricated as described herein. In this case, the system 1020, 1024 can comprise a general purpose computing device, which is programmed to implement a method of designing and/or fabricating the circuit 1026 including at least one semiconductor device 1016 as described herein.

In still another embodiment, the invention provides a computer program fixed in at least one computer-readable medium, which when executed, enables a computer system to implement a method of designing and/or fabricating a semiconductor device as described herein. For example, the computer program can enable the device design system 1010 to generate the device design 1012 as described herein. To this extent, the computer-readable medium includes program code, which implements some or all of a process described herein when executed by the computer system. It is understood that the term “computer-readable medium” comprises one or more of any type of tangible medium of expression, now known or later developed, from which a stored copy of the program code can be perceived, reproduced, or otherwise communicated by a computing device.

In another embodiment, the invention provides a method of providing a copy of program code, which implements some or all of a process described herein when executed by a computer system. In this case, a computer system can process a copy of the program code to generate and transmit, for reception at a second, distinct location, a set of data signals that has one or more of its characteristics set and/or changed in such a manner as to encode a copy of the program code in the set of data signals. Similarly, an embodiment of the invention provides a method of acquiring a copy of program code that implements some or all of a process described herein, which includes a computer system receiving the set of data signals described herein, and translating the set of data signals into a copy of the computer program fixed in at least one computer-readable medium. In either case, the set of data signals can be transmitted/received using any type of communications link.

In still another embodiment, the invention provides a method of generating a device design system 1010 for designing and/or a device fabrication system 1014 for fabricating a semiconductor device as described herein. In this case, a computer system can be obtained (e.g., created, maintained, made available, etc.) and one or more components for performing a process described herein can be obtained (e.g., created, purchased, used, modified, etc.) and deployed to the computer system. To this extent, the deployment can comprise one or more of: (1) installing program code on a computing device; (2) adding one or more computing and/or I/O devices to the computer system; (3) incorporating and/or modifying the computer system to enable it to perform a process described herein; and/or the like.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to an individual in the art are included within the scope of the invention as defined by the accompanying claims.

What is claimed is:

1. A heterostructure comprising:
a plurality of epitaxially grown layers, including:
an n-type contact layer; and
a mesa region adjacent to the n-type contact layer, the mesa region comprising an active layer and a p-type contact layer;
an n-type electrode to the n-type contact layer;
a p-type electrode to the p-type contact layer; and
an electrically insulating, thermally conductive semiconductor layer adjacent to the mesa region, wherein a thermal conductivity of the electrically insulating, thermally conductive semiconductor layer is at least five percent of the thermal conductivity of at least one of the plurality of epitaxially grown layers.

2. The heterostructure of claim 1, wherein the p-type electrode and the n-type electrode are embedded within the electrically insulating, thermally conductive semiconductor layer.

3. The heterostructure of claim 2, wherein the electrically insulating, thermally conductive semiconductor layer is electrically conductive.

4. The heterostructure of claim 3, further comprising a set of insulating materials located between the p-type electrode and the electrically insulating, thermally conductive semiconductor layer and the n-type electrode and the electrically insulating, thermally conductive semiconductor layer.

5. The heterostructure of claim 1, further comprising an interface layer located between the p-type contact layer of the mesa region and the electrically insulating, thermally conductive semiconductor layer.

6. The heterostructure of claim 1, further comprising a set of thermally conductive fillers within the electrically insulating, thermally conductive semiconductor layer.

7. The heterostructure of claim 1, further comprising a submount for mounting the heterostructure to fabricate an optoelectronic device, wherein the optoelectronic device is located within a package.

8. The heterostructure of claim 7, wherein the package is placed within a cavity of a heat sink for extracting heat generated from the optoelectronic device.

9. The heterostructure of claim 7, wherein the electrically insulating, thermally conductive semiconductor layer is located between the heterostructure and the package.

10. The heterostructure of claim 9, wherein the electrically insulating, thermally conductive semiconductor layer includes a plurality of thermally conductive nanoparticles.

11. An optoelectronic device, comprising:
a plurality of epitaxially grown layers, including:
a substrate;
an n-type contact layer to the substrate; and
a mesa region adjacent to the n-type contact layer, the mesa region comprising an active layer and a p-type contact layer;
an n-type electrode to the n-type contact layer;
a p-type electrode to the p-type contact layer; and
an electrically insulating, thermally conductive semiconductor layer adjacent to the mesa region, wherein a thermal conductivity of the electrically insulating, thermally conductive semiconductor layer is at least five percent of thermal conductivity of at least one of the plurality of epitaxially grown layers.

12. The device of claim 11, wherein the p-type electrode and the n-type electrode are embedded within the electrically insulating, thermally conductive semiconductor layer.

13. The device of claim 12, wherein the electrically insulating, thermally conductive semiconductor layer is electrically conductive.

14. The device of claim 13, further comprising a set of insulating materials located between the p-type electrode and the electrically insulating, thermally conductive semiconductor layer and the n-type electrode and the electrically insulating, thermally conductive semiconductor layer.

15. The device of claim 11, further comprising an interface layer located between the p-type contact layer of the mesa region and the electrically insulating, thermally conductive semiconductor layer.

16. The device of claim 11, further comprising a set of thermally conductive fillers within the electrically insulating, thermally conductive semiconductor layer.

17. A method of fabricating a device, the method comprising:
epitaxially growing a plurality of layers on a substrate, wherein the plurality of layers includes:
a substrate;
an n-type contact layer to the substrate;
a mesa region adjacent to the n-type contact layer, the mesa region comprising an active layer and a p-type contact layer; and
an electrically insulating, thermally conductive semiconductor layer adjacent to the mesa region, wherein a thermal conductivity of the electrically insulating, thermally conductive semiconductor layer is at least five percent of the thermal conductivity of at least one of the plurality of epitaxially grown layer.

18. The method of claim 17, further comprising:
etching a first portion of the plurality of layers to expose the n-type contact layer; and
forming an n-type electrode for contact to the n-type contact layer.

19. The method of claim 18, further comprising:
etching a second portion of the plurality of layers to expose the p-type contact layer; and
forming a p-type electrode for contact to the p-type contact layer.

20. The method of claim 19, further comprising epitaxially growing the plurality of layers includes epitaxially growing an interface layer between the mesa region and the electrically insulating, thermally conductive semiconductor layer.
